(19) United States
(12) Patent Application Publication
(10) Pub. No.: US 2015/0222230 A1
(43) Pub. Date: Aug. 6, 2015

(54) OUTPUT POWER TUNING USING PULSE POSITION AND PULSE WIDTH CONTROL IN A PULSE POSITION, PULSE WIDTH MODULATION AMPLIFIER

(71) Applicant: AURIGA MEASUREMENT SYSTEMS, LLC, Chelmsford, MA (US)

(72) Inventors: Yusuke Tajima, Acton, MA (US); John Muir, North Chelmsford, MA (US); David Wandrei, Sterling, MA (US)

(21) Appl. No.: 14/604,287

(22) Filed: Jan. 23, 2015

Related U.S. Application Data
(60) Provisional application No. 61/934,992, filed on Feb. 3, 2014.

(51) Int. Cl. H03F 1/02; H03F 3/21; H03F 3/19

(52) U.S. Cl. CPC H03F 1/02; H03F 3/19; H03F 3/211; H03F 2200/451; H03F 2200/351; H03F 2200/339

(57) ABSTRACT

An outphasing amplifier apparatus and method is disclosed that controls pulse width modulation and/or pulse height modulation to improve power-added-efficiency performance and/or compensate for errors caused by quantized pulse position settings is provided herein.

### RELATED APPLICATIONS

The present application claims priority under 35 U.S.C. §119(e) to U.S. Provisional Application 61/934,992, titled “OUTPUT POWER TUNING USING PULSE POSITION AND PULSE WIDTH CONTROL IN A PULSE POSITION, PULSE WIDTH MODULATION AMPLIFIER,” filed on Feb. 3, 2014, which is hereby incorporated herein by reference in its entirety.

### FIELD OF THE INVENTION

The subject matter described herein relates generally to radio frequency (RF) circuits and, more particularly, to techniques and circuits for operating RF amplifiers using pulse-modulated signals.

### BACKGROUND

Many modern communications applications require the transmission of signals having a varying envelope with a high peak-to-average ratio. To transmit such signals, it is important to use an RF amplifier or transmitter that is efficient over a wide dynamic range. Thus, it is desirable for the amplifier efficiency to be high under both average drive power and peak drive power conditions. In some applications, the difference between peak and average power levels can be as high as 10 dB or more.

When a signal envelope varies up to 10 dB, the optimum output impedance to achieve maximum efficiency in a power amplifier can vary dramatically. If the output load impedance stays constant while the envelope varies, inefficient amplifier operation will result. This is one reason that traditional power amplifier designs provide poor efficiency performance when used in high peak-to-average applications.

There is a need for techniques and circuits that are capable of providing efficient amplifier operation under high peak-to-average ratio conditions.

### SUMMARY

Techniques, systems, and circuits described herein relate to the use of pulse width and/or pulse position modulated signals in Chireix outphasing amplifiers to achieve efficient operation over a broad dynamic range. As such, the techniques and circuits are well suited for use within systems that use high peak-to-average ratio signals. The techniques and circuits are capable of maintaining both high drain efficiency (DE) and high power added efficiency (PAE) over the high dynamic range.

Unlike conventional Chireix outphasing amplifiers, some amplifiers described herein modulate both the pulse width and pulse position of signals to enhance back-off power-added-efficiency and minimize quantization noise. In addition or in alternative to pulse width modulation, in some embodiments, pulse height may also be modulated to increase amplitude accuracy and reduce quantization noise.

In various embodiments, the common position of pulses driving two amplifiers may be used to achieve phase modulation in an amplification system.

In various embodiments, the differential position of the pulses driving two amplifiers may be used to modulate the amplitude of the output power. In addition, pulse width may be modulated to achieve one or both PAE and/or to compensate for errors caused by the limited resolution of the differential time setting. Alternatively, in addition pulse height modulation may also be used to achieve one or both of PAE and/or to compensate for errors caused by the limited resolution of the differential time setting. One embodiment of a method of operating an outphasing amplifier including first and second amplifiers with pulse modulated signals, includes controlling an amplitude modulation of first and second pulse signals driving the first and second amplifiers by controlling a differential position of the first and second pulse signals, and modulating a pulse width of at least one of the first and second pulse signals to correct for errors caused by quantization of differential time difference settings.

This embodiment may further comprise modulating a pulse height of at least one of the first and second pulse signals to correct for errors caused by quantization of differential time difference settings. Alternatively, this embodiment may further comprise modulating a pulse height of at least one of the first and second pulse signals to improve power-added-efficiency of the amplifier.

Aspects of this embodiment may further comprise controlling the amplitude modulation of first and second pulse signals driving the first and second amplifiers comprises controlling programmable delay circuits at an input to the first and second amplifiers.

Aspects of this embodiment may further comprise adjusting chireix components of an outphasing combiner combining output signals from the first and second amplifiers. Aspects of this embodiment may further comprise providing differential bias voltages to the first and second amplifiers. Aspects of this embodiment may further comprise providing different amplifier sizes of the first and second amplifiers.

Another embodiment of a method of operating an outphasing amplifier including first and second amplifiers with pulse modulated signals, comprises controlling an amplitude modulation of first and second pulse signals driving the first and second amplifiers by controlling a differential position of the first and second pulse signals, and modulating a pulse width of at least one of the first and second pulse signals to improve power-added-efficiency of the amplifier.

This embodiment may further comprise modulating a pulse height of at least one of the first and second pulse signals to correct for errors caused by quantization of differential time difference settings. Alternatively, this embodiment may further comprise modulating a pulse height of at least one of the first and second pulse signals to improve power-added-efficiency of the amplifier. Aspects of this embodiment may further comprise controlling the amplitude modulation of first and second pulse signals driving the first and second amplifiers comprises controlling programmable delay circuits at an input to the first and second amplifiers.

Aspects of this embodiment may further comprise adjusting chireix components of an outphasing combiner combining output signals from the first and second amplifiers. Aspects of this embodiment may further comprise providing differential bias voltages to the first and second amplifiers. Aspects of this embodiment may further comprise providing different amplifier sizes of the first and second amplifiers.

Another embodiment of method of operating an outphasing amplifier including first and second amplifiers with pulse modulated signals, comprises controlling an amplitude modulation of first and second pulse signals driving the first and second amplifiers by controlling a differential position of the first and second pulse signals, and modulating a pulse height of at least one of the first and second pulse signals to correct for errors caused by quantization of differential time difference settings.

This embodiment may further comprise modulating a pulse width of at least one of the first and second pulse signals to correct for errors caused by quantization of differential time difference settings. This embodiment may alternatively further comprise modulating a pulse width of at least one of the first and second pulse signals to improve power-added-efficiency of the amplifier.

Aspects of this embodiment may further comprise controlling the amplitude modulation of first and second pulse signals driving the first and second amplifiers comprises controlling programmable delay circuits at an input to the first and second amplifiers.

Aspects of this embodiment may further comprise adjusting Chireix components of an outphasing combiner combining output signals from the first and second amplifiers. Aspects of this embodiment may further comprise providing differential bias voltages to the first and second amplifiers. Aspects of this embodiment may further comprise providing different amplifier sizes of the first and second amplifiers.

Another embodiment of a method of operating an outphasing amplifier including first and second amplifiers with pulse modulated signals, comprises controlling an amplitude modulation of first and second pulse signals driving the first and second amplifiers by controlling a differential position of the first and second pulse signals, and modulating a pulse height of at least one of the first and second pulse signals to improve power-added-efficiency of the amplifier.

This embodiment may further comprise modulating a pulse width of at least one of the first and second pulse signals to correct for errors caused by quantization of differential time difference settings. This embodiment may alternatively further comprise modulating a pulse width of at least one of the first and second pulse signals to improve power-added-efficiency of the amplifier.

Aspects of this embodiment may further comprise controlling the amplitude modulation of first and second pulse signals driving the first and second amplifiers comprises controlling programmable delay circuits at an input to the first and second amplifiers.

Aspects of this embodiment may further comprise adjusting Chireix components of an outphasing combiner combining output signals from the first and second amplifiers. Aspects of this embodiment may further comprise providing differential bias voltages to the first and second amplifiers. Aspects of this embodiment may further comprise providing different amplifier sizes of the first and second amplifiers.

According to some embodiments, when the output power requirement of an amplifier is small, PAE may be maintained by reducing pulse width to minimize the input power to the amplifier. Reduced pulse width may also reduce power dissipation in the driver stage, thereby increasing overall transmitter efficiency. Pulse width will not typically be reduced, however, below the point where the rise and fall time of the pulses start to impact amplifier efficiency by degrading gain, efficiency, and output power.

In some implementations, the pulse modulation techniques and circuitry described herein may be used to provide the dynamic re-configurability needed to support different communication standards. The techniques described herein are also capable of enhancing transmitter immunity to RF impairments such as I-Q imbalance, carrier leakage, and others. In some embodiments, the disclosed techniques and circuits may also eliminate the need for components to perform frequency conversion.

### BRIEF DESCRIPTION OF THE DRAWINGS

The foregoing features may be more fully understood from the following description of the drawings in which:

FIG. 1 is a block diagram illustrating a conventional Chireix amplifier circuit for amplifying radio frequency (RF) signals;

FIG. 2 is a plot showing the relationship between drain efficiency and output power level for a Chireix amplifier that adjusts output power by changing the differential position of two pulse trains;

FIG. 3 is a plot showing output power as a function of differential time for a Chireix amplifier that adjusts output power by changing the differential position of two pulse trains;

FIG. 4 is a block diagram illustrating an exemplary pulse position, pulse width modulation amplifier circuit in accordance with an embodiment;

FIG. 5 is a schematic diagram illustrating an exemplary outphasing combiner used in an amplifier in accordance with an embodiment;

FIG. 6 is a plot showing output power as a function of duty cycle (pulse width) for different differential pulse positions in accordance with an embodiment; and

FIG. 7 is a plot showing the sensitivity of output power to pulse height for different differential pulse positions in accordance with an embodiment.

### DETAILED DESCRIPTION

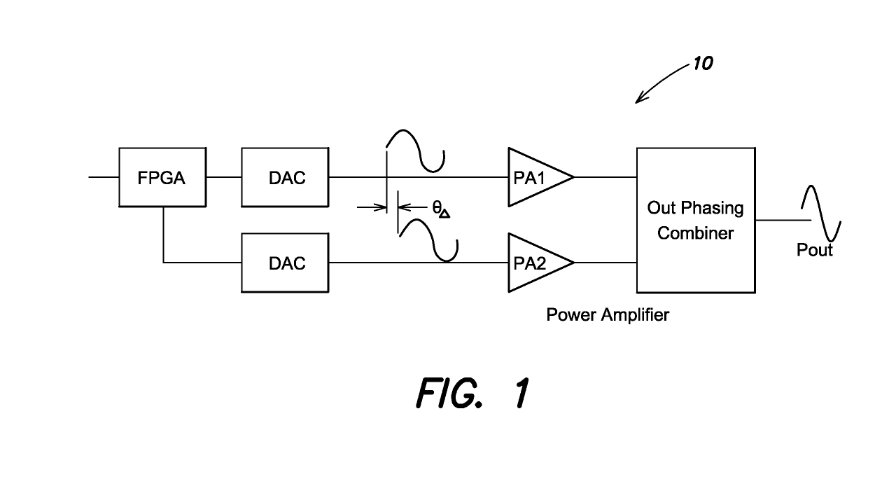

FIG. 1 is a block diagram illustrating a conventional Chireix (outphasing) amplifier circuit 10 for amplifying radio frequency (RF) signals. As shown, the amplifier circuit 10 includes a pair of amplifiers PA1 and PA2 which may be provided as, for example, RF power amplifiers. The two amplifiers PA1, PA2 receive RF signals from a pair of digital-to-analog converters (DACs) at respective inputs with a relative phase difference of θ_{Δ}. Amplified signals at the outputs of the amplifiers PA1, PA2 are combined in an outphasing combiner. In some embodiments, the outphasing combiner may include Chireix components that are constructed with lumped and/or transmission line components. The input signals to PA1 and PA2 are sinusoidal RF signals having a differential phase shift θ_{Δ}, as shown in FIG. 1. The input signals of PA1 and PA2 may be generated using a field programmable gate array (FPGA) and the DACs.

Chireix amplifiers provide a mechanism for modifying the output impedance seen by an amplifier as the envelope of the signal changes. In a conventional Chireix amplifier circuit, two amplifiers (similar to PA1, PA2 of FIG. 1) operating at maximum power are combined through a low-loss combiner (similar to outphasing combiner of FIG. 1). The combined power at the output port of the combiner (denoted herein as P_{out, combined}) will vary as the differential phase (θ_{Δ}) between the two amplifier outputs varies. The relationship may be expressed as follows:

P_{out, combined}=2×Pₒᵤₜ×cos²(θ_{Δ}/2), (1)

where Pₒᵤₜ is the output power of each amplifier. The load impedance (R_{L}) seen by the power amplifier is also modulated by the varying differential phase (θ_{Δ}) as follows:

R_{L}=R_{L0}/cos²(θ_{Δ}/2), (2)

where R_{L0} is the load impedance at θ_{Δ}=0. By modulating the differential phase (θ_{Δ}), the amplitude of the output power will be modulated according to Equation (1) and the load impedance will be modulated according to Equation (2), which results in efficiency improvement at back-off power levels.

The asymmetric components added in the combiner of the Chireix amplifier can even further improve back-off efficiency when θ_{Δ} is approaching 90 degrees (see, e.g., “High Power Out Phasing Modulation,” by H. Chireix, Proc. IRE, vol. 23, No. 11, pp. 1370-1392, November 1935). Therefore, Equations (1) and (2) above are only approximations for the Chireix amplifier.

Techniques for driving a Chireix amplifier with a train of pulses, rather than a sinusoidal signal, have been described in a variety of publications. One such technique, and related system, is described in U.S. Pat. No. 8,174,322 to Heijden et al. entitled “Power Control of Reconfigurable Outphasing Chireix Amplifiers and Methods,” filed on Mar. 21, 2011 and issued on May 8, 2012, which incorporated herein by reference in its entirety. Publications also show pulse driven Class E amplifiers used in Chireix amplifiers. Such systems are described in, for example, “Asymmetric Multilevel Outphasing Transmitter Using Class-E PAs with Discrete Pulse Width Modulation,” by Chung et al., IEEE MTT-S International Microwave Symposium Digest (MTT), pp. 264-267, 2010; and “A Fully-Integrated All Digital Outphasing Transmitter,” PhD Dissertation by Kwan-Woo Kim, Georgia Institute of Technology, December 2009.

In these systems, the amplitude modulation is accomplished by controlling the differential position (t_{Δ}) of two pulses driving amplifiers. Class E switching amplifiers used in these systems have enough frequency selectivity to make the Chireix combiner work as if it is being driven by sinusoidal signals. Fundamental frequency components of the output signals of the amplifiers are combined by the same mechanism explained in Equations (1) and (2) above. Therefore, by modulating the differential position (t_{Δ}) of two pulse trains, the output power of the Chireix combiner can be amplitude modulated while achieving a desired back-off efficiency for substantially the same reasons described above. Output power of the fundamental component (denoted herein as P_{out, fo}) may be described as a function of the differential position (t_{Δ}) as follows:

P_{out, fo}=2×Pₒᵤₜ×cos²(2π*t_{Δ}/t_{ωo}), (3)

where t_{ωo} represents one cycle at the carrier frequency.

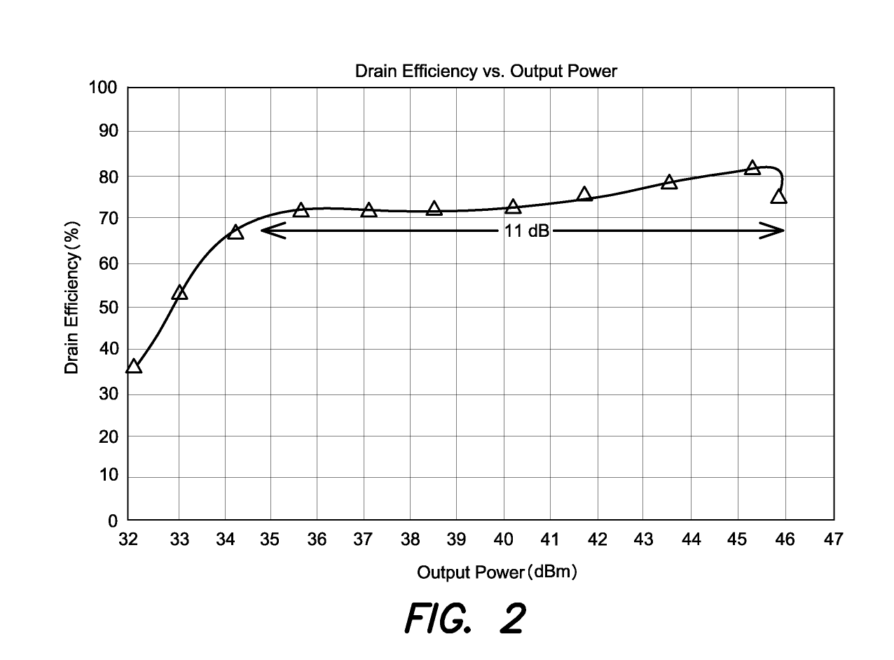

FIG. 2 is a plot showing the relationship between drain efficiency and output power level for a Chireix amplifier that adjusts output power by changing the differential position (t_{Δ}, indicated by Δ) of two pulse trains. As illustrated, a drain efficiency (DE) of more than 70% may be achieved over 11 dB of dynamic range. However, although a high drain efficiency is achieved over a wide dynamic range, the power amplifier associated with the plot of FIG. 2 has difficulty achieving good power-added-efficiency (PAE). PAE and DE are both functions of Pout and Pin and may be expressed as:

PAE=(Pout−Pin)/Pout, (4)

DE=Pout/Pin. (5)

In the Heijden patent described above, the signal pulse width is maintained at a constant value for all power levels. Therefore, input power is constant, even at low output power levels. With reference to Equation (4) above, it is seen that this condition can degrade PAE in the back-off, even if drain-efficiency remains high. To improve PAE, it has been found that the input power of an amplifier could be reduced proportionally with the output power without changing the peak voltage of the pulses. Thus, in some embodiments described herein, methods and circuits are provided that reduce the input power of a Chireix amplifier using pulse width modulation (PWM) to maintain the PAE at back-off.

The outphasing configuration removes all of the amplitude modulation requirements to phase modulation and puts the burden of accuracy on the phase setting accuracy. In a pulse driven outphasing configuration, this accuracy is translated to the differential position t_{Δ}. In Heijden's method, for example, pulse-width is kept constant and power level modulation is fully accomplished by the modulation of differential pulse position t_{Δ}, for any given frequency band. If the differential pulse position is moved from t_{Δ} to (t_{Δ}+Δₜ), the amplitude will change to Pout+ΔPout, which results in AM quantization noise. This error can be derived from Equation (3) as:

ΔPout=d(Pout)/dt_{Δ}*Δₜ. (6)

Equation (6) is for an ideal case where no Chireix compensation components are used in the combiner and is therefore only an approximation of the performance of a power amplifier that uses Chireix compensation components in the combiner.

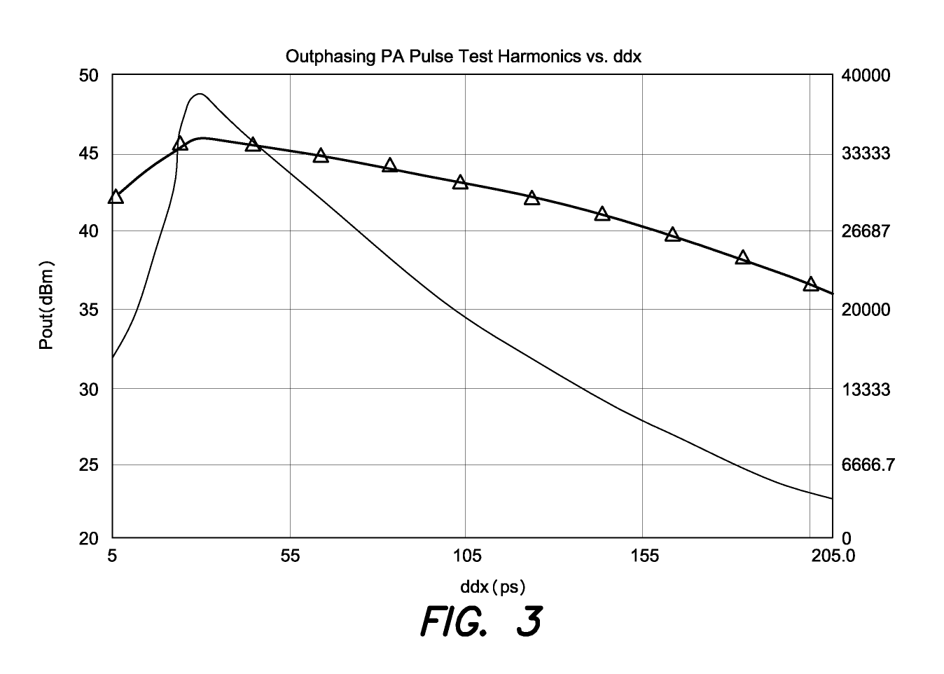

FIG. 3 is a plot showing output power as a function of differential time Δₜ for a Chireix amplifier (one curve shows dBm versus Δₜ and the other shows milliWatts versus Δₜ). As can be seen, the sensitivity in this example is about:

ΔPout/Δₜ=0.05 dB/ps. (7)

If the resolution of the pulse position setting is 10 picoseconds (pS), the error can be as much as 0.5 dB. As will be appreciated, this amount of error can degrade the quality of a corresponding communication. According to aspects of some embodiments, it is therefore desirable to provide compensation to reduce the error. In some embodiments, PWM and/or pulse amplitude modulation are used to compensate for this error.

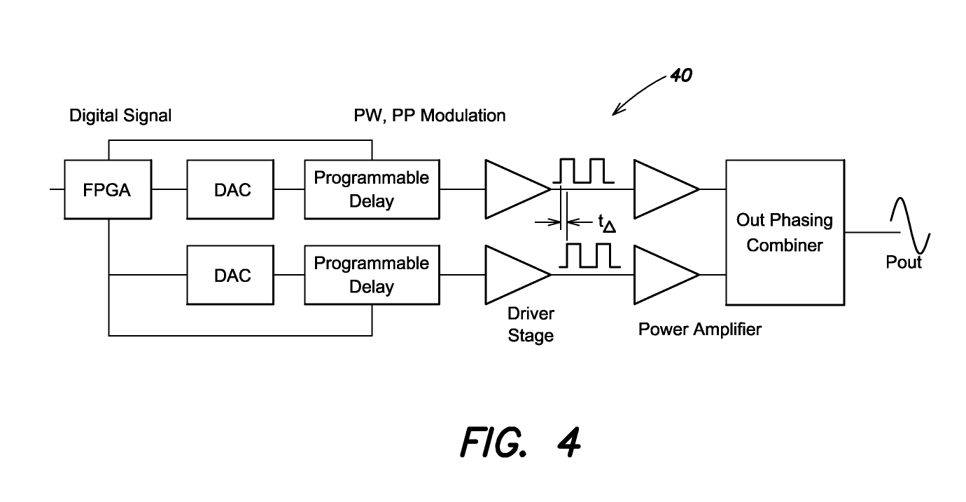

FIG. 4 is a block diagram illustrating an exemplary amplifier circuit 40 in accordance with an embodiment of the present disclosure. In amplifier circuit 40, signals generated by the FPGA and DACs, wherein the DACs may be RF DACs, are trains of pulses with a pulse width, pulse position, and/or pulse height modulated to operate an outphasing final stage. At the outputs of the DACs, optional programmable delay circuits may be used to fine adjust the common and relative position of the trains of pulses, wherein the FPGA can be configured to control the delay values of the programmable delays via control lines, as shown in FIG. 4. The outputs from the programmable delay circuits (if present) drive the PAs (PA1, PA2) (which may include an optional driver stage in front of the PAs). In some embodiments, class E switching amplifiers are used for the PAs. Output signals from the PAs (PA1 and PA2) are combined through the outphasing combiner to generate the output signal (Pout) of the amplifier circuit 40.

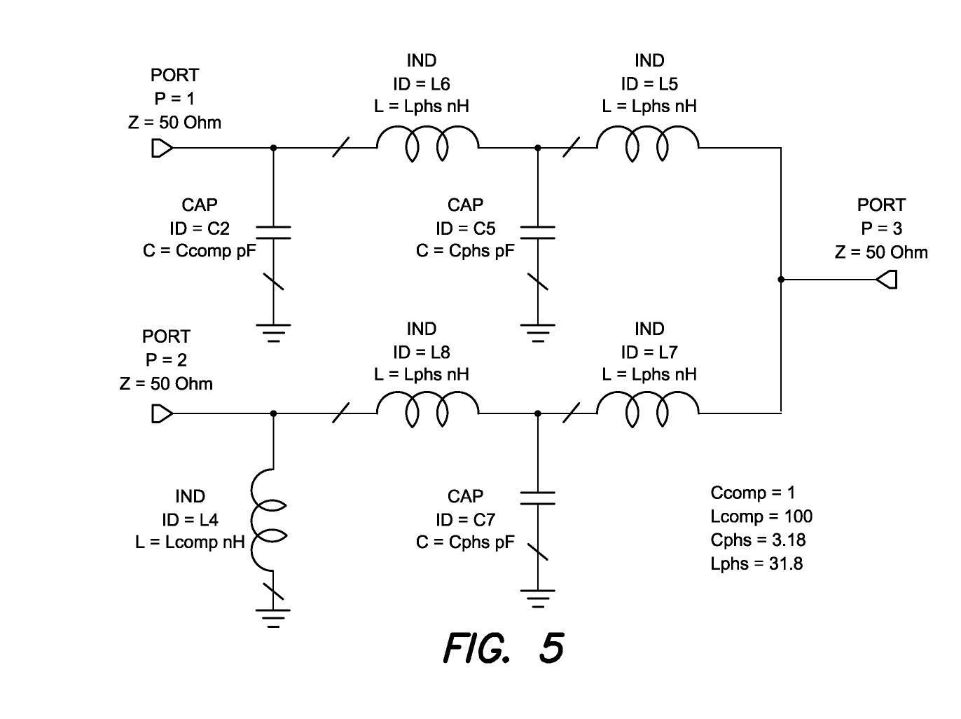

FIG. 5 is a schematic diagram illustrating an exemplary outphasing combiner design that may be used in accordance with an embodiment, comprising a plurality of input ports (P=1, P=2), an exemplary arrangement of inductors and capacitors, and an output port (P=3). It is to be appreciated that many alternative combiner designs may be used in various embodiments of this disclosure.

In some embodiments, the position of the pulses driving the PAs, and optionally the signals received by the outphasing combiner, are modulated in sync at a common position to reflect changing phase states of the signal. When in a common position, the signals driving each PA have the same phase modulation or pulse position modulation as the original signal, wherein the signals driving each PA are the substantially the same except they are shifted relative to each other (differential position) based on the desired signal amplitude. The differential position of the pulses may be used to control the amplitude of the output power. According to aspects of some embodiments of the disclosure, pulse width and pulse height may be modulated to improve the PAE, especially at lower output power, and/or to correct for the error caused by the limited resolution of the differential time setting. Small variations in the pulse width and height can produce an offset necessary to correct the error caused by the minimum resolution in the differential time setting.

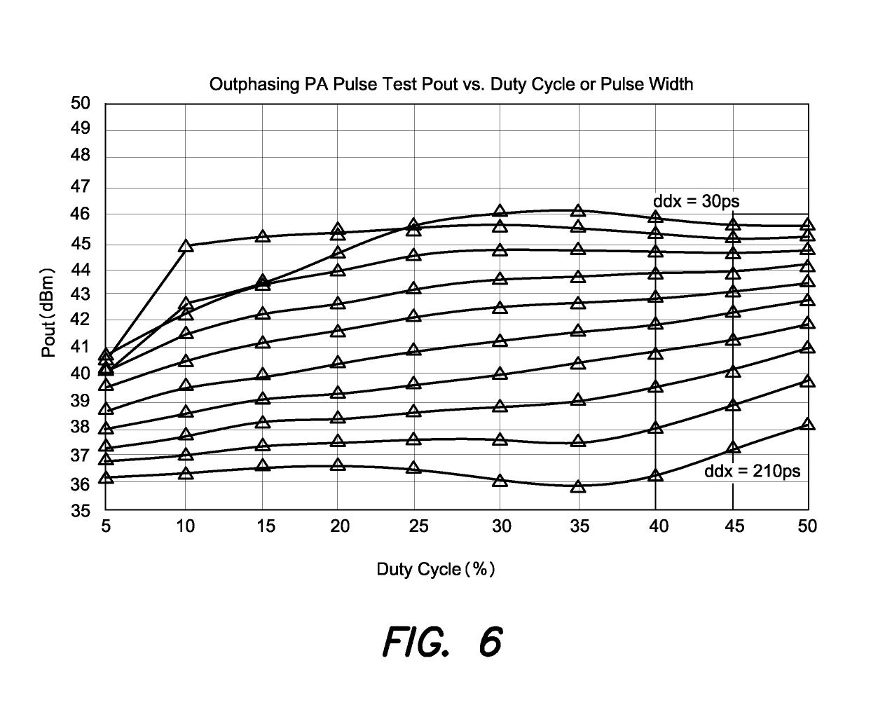

FIG. 6 is a plot showing outphasing output power (in dBm) of an exemplary outphasing combiner, for example, as a function of duty cycle (%) at different differential pulse positions (i.e., different values of t_{Δ}, indicated by ddx) for an exemplary implementation. In this figure, duty cycle is calculated from pulse width (PW) using the following equation:

Duty Cycle=PW/Pwc, (9)

where Pwc is the pulse period of the carrier frequency. In this example, the carrier frequency is 2 GHz and Pwc is 500 ps.

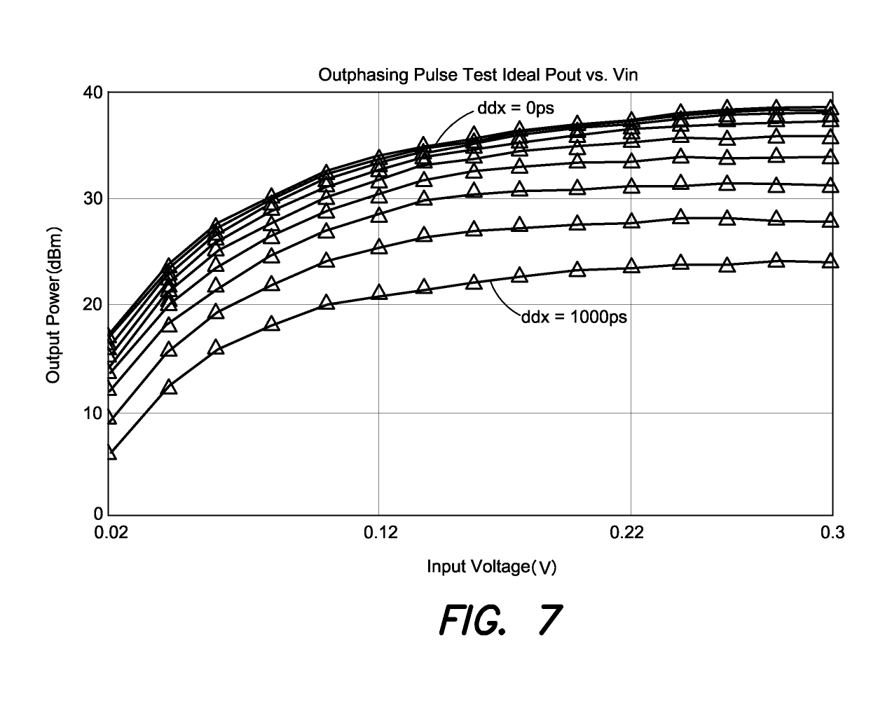

FIG. 7 shows the sensitivity of output power to the height (i.e., peak voltage) of the pulses at different differential pulse positions (ddx, or t_{Δ}) between the two pulses, ranging from 0 to 1000 psec, as depicted in the figure by ddx=0 ps and ddx=1000 ps. The sensitivity to the output power derived from this figure is approximately given by ΔPout/ΔPv=0.02 dB/mV. In some embodiments, this sensitivity may be used to correct the error caused by the quantization error due to phase setting error.

As described previously in conjunction with FIG. 4, to further improve the overall phase accuracy of the system disclosed herein, optional programmable delay circuits (particularly, a first set of programmable delay circuits) may be placed after corresponding DACs. The programmable delay circuits are capable of adjusting the delay of pulses flowing through them. In some embodiments, this capability is used to fine adjust the common position of the pulses to improve the accuracy of phase modulation. In at least one embodiment, a second set of programmable delay circuits (not illustrated) may also be inserted before, in parallel with, or after the first set of programmable delay circuits to fine adjust the relative position between the two pulses to further improve the accuracy of amplitude modulation.

In some embodiments, the sensitivity of output power to pulse width and height (as described above, ΔPout/ΔPv) may be used to offset the sensitivity to differential position of the pulses. According to some embodiments, an FPGA can be configured to adjust the pulse width, pulse position, and pulse height of the specific pulse chains received by the PAs to achieve a desired output signal at the output of the combiner in accordance with a pre-distortion algorithm. The pre-distortion algorithm can, for example, determine how to set the delays to perform the desired compensation. Alternative types of programmable devices (besides the FPGA (and/or other type of processor(s)) may also be used with the system disclosed herein including, for example, general purpose microprocessors, digital signal processors (DSPs), reduced instruction set computers (RISCs), complex instruction set computers (CISC), application specific integrated circuits (ASICs), microcontrollers, embedded processors, dual core processors, processors complexes, and/or others, including combinations of the above. It is appreciated that any combination of modulation of pulse width, pulse position, and pulse height can be used to improve either or both of PAE and/or offset the sensitivity to differential position of the pulses.

It is to be appreciated that additional dynamic output power range control may be achieved in any of the herein disclosed implementations by optimizing asymmetric operation of the amplifier according to additional techniques and structure. These additional techniques and structure may include optimization of: (1) Chireix components: shunt capacitor (or open stub) and shunt inductor (or shorted stub) at the combiner ports A and B, respectively; (2) differential bias voltages (Va, Vb) applied to the amplifiers attached to ports A and B, respectively, (Va>Vb); (3) differential pulse widths (Wa, Wb) applied to amplifiers attached to ports A and B, respectively (Wa>Wb); and (4) different amplifier sizes.

Having described preferred embodiments which serve to illustrate various concepts, circuits, and techniques which are the subject of this patent, it will now become apparent to those of ordinary skill in the art that other embodiments incorporating these concepts, circuits, and techniques may be used. For example, described herein are specific exemplary circuit topologies and specific circuit implementations for achieving a desired performance. It is recognized, however, that the concepts and techniques described herein may be implemented using other circuit topologies and specific circuit implementations. Accordingly, it is submitted that that scope of the patent is not limited to the described embodiments, but rather should be limited only by the spirit and scope of the following claims.

What is claimed is:

1. A method of operating an outphasing amplifier including first and second amplifiers with pulse modulated signals, comprising:
controlling an amplitude modulation of first and second pulse signals driving the first and second amplifiers by controlling a differential position of the first and second pulse signals; and
modulating a pulse width of at least one of the first and second pulse signals to correct for errors caused by quantization of differential time difference settings.

2. The method as claimed in claim 1, further comprising modulating a pulse height of at least one of the first and second pulse signals to correct for errors caused by quantization of differential time difference settings.

3. The method as claimed in claim 1, further comprising modulating a pulse height of at least one of the first and second pulse signals to improve power-added-efficiency of the amplifier.

4. The method as claimed in claim 1, further comprising adjusting Chireix components of an outphasing combiner combining output signals from the first and second amplifiers.

5. The method as claimed in claim 1, further comprising providing differential bias voltages to the first and second amplifiers.

6. A method of operating an outphasing amplifier including first and second amplifiers with pulse modulated signals, comprising:
controlling an amplitude modulation of first and second pulse signals driving the first and second amplifiers by controlling a differential position of the first and second pulse signals;
modulating a pulse width of at least one of the first and second pulse signals to improve power-added-efficiency of the amplifier.

7. The method as claimed in claim 6, further comprising modulating a pulse height of at least one of the first and second pulse signals to correct for errors caused by quantization of differential time difference settings.

8. The method as claimed in claim 6, further comprising modulating a pulse height of at least one of the first and second pulse signals to improve power-added-efficiency of the amplifier.

9. The method as claimed in claim 6, further comprising adjusting Chireix components of an outphasing combiner combining output signals from the first and second amplifiers.

10. The method as claimed in claim 6, further comprising providing differential bias voltages to the first and second amplifiers.

11. A method of operating an outphasing amplifier including first and second amplifiers with pulse modulated signals, comprising:
controlling an amplitude modulation of first and second pulse signals driving the first and second amplifiers by controlling a differential position of the first and second pulse signals;
modulating a pulse height of at least one of the first and second pulse signals to correct for errors caused by quantization of differential time difference settings.

12. The method as claimed in claim 11, further comprising modulating a pulse width of at least one of the first and second pulse signals to correct for errors caused by quantization of differential time difference settings.

13. The method as claimed in claim 11, further comprising modulating a pulse width of at least one of the first and second pulse signals to improve power-added-efficiency of the amplifier.

14. The method as claimed in claim 11, further comprising adjusting Chireix components of an outphasing combiner combining output signals from the first and second amplifiers.

15. The method as claimed in claim 11, further comprising providing differential bias voltages to the first and second amplifiers.

16. A method of operating an outphasing amplifier including first and second amplifiers with pulse modulated signals, comprising:
controlling an amplitude modulation of first and second pulse signals driving the first and second amplifiers by controlling a differential position of the first and second pulse signals;
modulating a pulse height of at least one of the first and second pulse signals to improve power-added-efficiency of the amplifier.

17. The method as claimed in claim 16, further comprising modulating a pulse width of at least one of the first and second pulse signals to correct for errors caused by quantization of differential time difference settings.

18. The method as claimed in claim 16, further comprising modulating a pulse width of at least one of the first and second pulse signals to improve power-added-efficiency of the amplifier.

19. The method as claimed in claim 16, further comprising adjusting Chireix components of an outphasing combiner combining output signals from the first and second amplifiers.

20. The method as claimed in claim 16, further comprising providing differential bias voltages to the first and second amplifiers.
